(19) United States
(12) Patent Application Publication
(10) Pub. No.: US 2008/0308833 A1
(43) Pub. Date: Dec. 18, 2008

(54) Group III nitride-based compound semiconductor light-emitting device

(75) Inventors: Miki Moriyama, Aichi-ken (JP); Koichi Goshonoo, Aichi-ken (JP); Taro Hitosugi, Yamato-city (JP); Tetsuya Hasegawa, Tokorozawa-city (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: TOYODA GOSEI CO., LTD., Aichi-ken (JP); KANAGAWA ACADEMY OF SCIENCE AND TECHNOLOGY, Kawasaki-shi (JP)

(21) Appl. No.: 12/153,787

(22) Filed: May 23, 2008

(30) Foreign Application Priority Data
May 25, 2007 (JP) 2007-139637

(51) Int. Cl. H01L 33/00

(52) U.S. Cl. 257/99; 257/E33.064

(57) ABSTRACT

The refractive index of a titanium oxide layer is modified by adding an impurity (e.g., niobium (Nb)) thereto within a range where good electrical conductivity is obtained. The Group III nitride-based compound semiconductor light-emitting device of the invention includes a sapphire substrate, an aluminum nitride (AlN) buffer layer, an n-contact layer, an n-cladding layer, a multiple quantum well layer (emission wavelength: 470 nm), a p-cladding layer, and a p-contact layer. On the p-contact layer is provided a transparent electrode made of niobium titanium oxide and having an embossment. An electrode is provided on the n-contact layer. An electrode pad is provided on a portion of the transparent electrode. Since the transparent electrode is formed from titanium oxide containing 3% niobium, the refractive index with respect to light (wavelength: 470 nm) becomes almost equal to that of the p-contact layer. Thus, the total reflection at the interface between the p-contact layer and the transparent electrode can be avoided to the smallest possible extent. In addition, by virtue of the embossment, light extraction performance is increased by 30%.

### BACKGROUND OF THE INVENTION

1. Field of the Invention

The present invention relates to a Group III nitride-based compound semiconductor light-emitting device exhibiting improved light extraction performance. As used herein, “Group III nitride-based compound semiconductor” encompasses a semiconductor represented by the formula AlₓGa_{y}In_{1-x-y}N (0≦x≦1, 0≦y≦1, 0≦x+y≦1); such a semiconductor containing a predetermined element so as to attain, for example, an n-type/p-type conduction; and such a semiconductor in which a portion of a Group III element is substituted by B or Tl, and a portion of the Group V element is substituted by P, As, Sb, or Bi.

2. Background Art

Generally, Group III nitride-based compound semiconductor light-emitting devices employ a Group III nitride-based compound semiconductor having a refractive index as high as about 2.5. Therefore, in such devices, total reflection of light is likely to occur at the interface between a layer made of a Group III nitride compound semiconductor (e.g., a GaN layer), and a protective layer, insulating layer, or electrode layer which is made of a material other than the Group III nitride compound semiconductor and which exhibits a low refractive index, resulting in low performance in extraction of light from a light-emitting layer to the outside. Countermeasures have been taken. For example, Japanese Patent Application Laid-Open (kokai) No. 2000-196152 and 2006-294907 disclose a semiconductor light-emitting device in which the uppermost layer (p-GaN layer) is covered with a transparent electrode having, on a surface thereof, an embossment. In the devices, light is extracted, without total reflection, through the embossed surface of the transparent electrode at a region on which a pad electrode is not formed.

Meanwhile, the present inventors previously reported a technique for imparting electrical conductivity to titanium oxide (TiO₂) (see WO 2006/073189).

### SUMMARY OF THE INVENTION

The present inventors have found that when an impurity (e.g., niobium (Nb) or tantalum (Ta)) is added to impart electrical conductivity to titanium oxide (TiO₂) within a range where good electrical conductivity is obtained, the refractive index of titanium oxide can be successfully regulated. The present invention has been accomplished on the basis of this finding.

In a first aspect of the present invention, there is provided a Group III nitride-based compound semiconductor light-emitting device having a transparent electrode, wherein the transparent electrode comprises titanium oxide which is doped with at least one selected from a group consisting of niobium (Nb), tantalum (Ta), molybdenum (Mo), arsenic (As), antimony (Sb), aluminum (Al), and tungsten (W) at a ratio by mole with respect to titanium (Ti) of 1 to 10%, and the transparent electrode has, on at least a portion thereof, an embossment.

In a second aspect of the present invention, the transparent electrode comprises at least one selected from a group consisting of niobium titanium oxide and tantalum titanium oxide in which the ratio by mole of niobium (Nb) and tantalum (Ta) to titanium (Ti) is 3 to 10%, respectively.

In a third aspect of the present invention, the light-emitting device comprises a Group III nitride-based compound semiconductor contact layer, and, between the transparent electrode and the contact layer, there is no such a layer that is made of a material other than a material of the contact layer and the transparent electrode.

In a fourth aspect of the present invention, the transparent electrode is in contact with the contact layer, and the ratio of the refractive index of the transparent electrode to that of the contact layer is 0.98 to 1.02.

In a fifth aspect of the present invention, the light-emitting device comprises a Group III nitride-based compound semiconductor contact layer, and has, between the transparent electrode and the contact layer made of a Group III nitride-based compound semiconductor, only a transparent, electrically conductive layer which is made of a material other than a material of the contact layer and the transparent electrode and which has a thickness that is one quarter or less the wavelength of an emitted light in the transparent, electrically conductive layer. The transparent, electrically conductive layer is not limited to a single layer, and encompasses a multi-layer film having a total thickness of 100 nm or less. As used herein, the term “transparent electrode (or layer)” refers to an electrode (or layer) which is substantially transparent with respect to at least light emitted from the light-emitting device of the present invention.

In a sixth aspect of the present invention, the transparent electrode is a p-electrode. In a seventh aspect of the present invention, the transparent electrode is an n-electrode.

When titanium oxide (TiO₂) is doped with an impurity such as niobium (Nb) or tantalum (Ta), the resistivity of the doped oxide is considerably reduced. According to the present inventors' new finding, when titanium (Ti) in titanium oxide (TiO₂) is substituted by niobium (Nb) or tantalum (Ta) in an amount of 1 to 10 mol %, the refractive index (with respect to light of 360 nm to 600 nm) of the doped oxide becomes almost equal to that of gallium nitride. FIG. 5 is a graph showing variations in refractive index of tantalum titanium oxide (Ti₁₋ₓTaₓO₂) with respect to light of 400 nm to 800 nm, when the compositional proportion x of tantalum is varied from 0.01 to 0.2 (six values). Similar results are obtained when another impurity (e.g., niobium (Nb)) is added to titanium oxide. Meanwhile, according to, for example, Advanced Electronics Series I-21 “Group III Nitride Semiconductor,” written and edited by Isamu Akasaki, Baifukan Co., Ltd., page 57, FIG. 3.12, GaN has a refractive index of about 2.74 at a wavelength of 370 nm, about 2.57 at 400 nm, about 2.45 at 500 nm, or about 2.40 at 600 nm.

According to the present inventors' previous finding, when an impurity such as niobium (Nb) or tantalum (Ta) is added to titanium oxide (TiO₂) in an amount of 1 to 10 mol %, the doped oxide exhibits a resistivity of about 5×10⁻⁴ Ωcm or less (see WO 2006/073189).

On the basis of the above finding, for example, an electrode layer of a Group III nitride-based compound semiconductor device can be made from titanium oxide (TiO₂) doped with an impurity such as niobium (Nb) or tantalum (Ta) in an amount of 1 to 10%, and the total reflection of light of 360 nm to 600 nm at the interface between such an impurity-doped titanium oxide (TiO₂) layer and a Group III nitride layer (e.g., a gallium nitride layer) can be suppressed to the smallest possible extent. As described hereinbelow, the refractive index of a titanium oxide (TiO₂) layer doped with an impurity such as niobium (Nb) or tantalum (Ta) can be controlled to be higher than that of a Group III nitride layer (e.g., a gallium nitride layer) at a predetermined wavelength within a range of, for example, 400 nm to 600 nm by controlling the doping amount of such an impurity. Therefore, for example, UV light transmitted from the gallium nitride layer to the thus-doped titanium oxide (TiO₂) layer can be prevented by total reflection from returning to the gallium nitride layer.

A contact layer which is joined directly to the transparent electrode may be made of gallium nitride or a Group III nitride-based compound semiconductor having a predetermined composition. As has been known, the refractive index of a Group III nitride-based compound semiconductor is varied with the compositional proportion of the Group III element or the amount of an impurity added to the semiconductor. Therefore, most preferably, the amount of an impurity such as niobium (Nb) or tantalum (Ta) added to titanium oxide (TiO₂) is controlled so that the refractive index of the transparent electrode becomes equal to that of the contact layer which is joined directly thereto. In this preferred case, no total reflection of light occurs. Even when the refractive index of the transparent electrode is not completely equal to that of the contact layer, from the viewpoint of reduction in total reflection, the ratio of the refractive index of the transparent electrode to that of the contact layer is preferably 0.95 to 1.05, more preferably 0.98 to 1.02, much more preferably 0.99 to 1.01. In this case, with respect to change in amount of an impurity (e.g., niobium (Nb) or tantalum (Ta)) added to titanium oxide (TiO₂) within a range of 1 to 10 mol %, change in refractive index is large, but change in electrical conductivity (resistivity) is relatively small. Therefore, the amount of such an impurity added can be determined so that electrical conductivity is maintained at the highest possible level (i.e., resistivity is maintained at the lowest possible level), and that refractive index is regulated to a predetermined value.

In general, the refractive index of a medium is positively correlated with the density of the medium. Therefore, it should be noted that the refractive index of an oxide film is reduced as the density thereof decreases.

Thus, when a titanium oxide (TiO₂) layer having a predetermined refractive index and a sufficiently reduced resistivity, which have been attained through control of the amount of an impurity (e.g., niobium (Nb) or tantalum (Ta)) added thereto, is employed as an electrode of a Group III nitride-based compound semiconductor light-emitting device, failure of extraction of light from a GaN layer, which would otherwise be caused by total reflection of light at least at the interface between the electrode and the GaN layer, can be avoided. A process for forming a thick titanium oxide (TiO₂) layer and providing an embossment thereon is much easier to perform than a process for providing an embossment on a gallium nitride layer, which cannot be thickened due to its high electrical resistance. According to the present invention, light extraction performance is increased by 30%.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with accompanying drawings, in which:

FIG. 1 is a cross-sectional view of the configuration of a Group III nitride-based compound semiconductor light-emitting device 100 according to Embodiment 1 of the present invention;

FIG. 2 is a cross-sectional view of the configuration of a Group III nitride-based compound semiconductor light-emitting device 200 according to Embodiment 2 of the present invention;

FIG. 3A is a cross-sectional view of the configuration of a Group III nitride-based compound semiconductor light-emitting device 300 according to Embodiment 3 of the present invention;

FIG. 3B is a cross-sectional view of the configuration of a Group III nitride-based compound semiconductor light-emitting device 310, which is a modification of Embodiment 3;

FIG. 4A is a cross-sectional view of the configuration of a Group III nitride-based compound semiconductor light-emitting device 400 according to Embodiment 4 of the present invention;

FIG. 4B is a cross-sectional view of the configuration of a Group III nitride-based compound semiconductor light-emitting device 410, which is a modification of Embodiment 4;

FIG. 4C is a cross-sectional view of the configuration of a Group III nitride-based compound semiconductor light-emitting device 420, which is another modification of Embodiment 4; and

FIG. 5 is a graph showing dispersion of the refractive index of tantalum titanium oxide corresponding to change in compositional proportion of tantalum.

### DETAILED DESCRIPTION OF PREFERRED EMBODIMENTS

The impurity-doped titanium oxide (TiO₂) layer of the invention may be formed by any known technique; for example, pulsed laser deposition described in WO 2006/073189, or sputtering. The target employed for formation of the layer may be a sintered target prepared in advance by mixing titanium oxide (TiO₂) with niobium oxide (Nb₂O₃) or tantalum oxide (Ta₂O₅) so that the ratio by mole of titanium (Ti) to niobium (Nb), tantalum (Ta), or another impurity becomes a predetermined value. The sintered target formed of such a mixture is prepared by mixing finely divided particles of the respective oxides, followed by heating. Layer formation may be performed through reactive sputtering by using, as a target, a Ti—Nb alloy or Ti—Ta alloy in which the ratio by mole of titanium (Ti) to niobium (Nb) or tantalum (Ta) has been regulated to a predetermined value.

For example, when the titanium oxide layer is formed so that the refractive index of the layer becomes equal to that of gallium nitride (GaN) at 460 nm or thereabouts (i.e., 2.48), the amount of tantalum (Ta) or niobium (Nb) added to titanium oxide (TiO₂) is preferably 3 to 10 mol %, more preferably 6 to 8%. When the titanium oxide layer is formed so that the refractive index of the layer becomes equal to that of gallium nitride (GaN) at 520 nm or thereabouts (i.e., 2.43), the amount of tantalum (Ta) or niobium (Nb) added to titanium oxide (TiO₂) is preferably 3 to 10 mol %, more preferably 3 to 5 mol %.

The titanium oxide (TiO₂) layer formed may be a rutile-type TiO₂ layer having higher density, or an anatase-type TiO₂ layer having lower density. From the viewpoint of reduction in electrical resistance, an anatase-type TiO₂ layer is more preferred. And also the Group III nitride-based compound semiconductor light-emitting layer may be formed of a single layer, a single quantum well (SQW) layer, or a multiple quantum well (MQW) layer.

When the Group III nitride-based compound semiconductor light-emitting device is formed through epitaxial growth, which is a generally employed semiconductor production technique, followed by formation of an impurity-doped titanium oxide (TiO₂) electrode on the uppermost layer (p-layer) of the light-emitting device, the doped titanium oxide (TiO₂) electrode serves as a p-electrode. In this case, when at least one of a Bragg reflection layer formed of multiple transparent layers and a highly reflective metal layer is provided on the bottom surface of an epitaxial growth substrate, light diverging to the bottom surface of the epitaxial growth substrate can be effectively employed.

An embossment, i.e., concave and convex configuration, may be provided on an exposed surface of the doped titanium oxide (TiO₂) electrode through any known technique, such as etching, nanoimprinting, electron beam lithography, or binding of fine titanium oxide (TiO₂) particles to the exposed surface.

Etching may be carried out through the following procedure. Firstly, a resist mask is patterned through photolithography. Examples of the thus-formed pattern, i.e., concave and convex configuration, include a dot pattern, a grid pattern, and a stripe pattern. The pattern may be periodically or non-periodically arranged as desired. The width or pitch (interval) of openings of the mask is preferably 3 μm or less. More preferably, when λ represents emission wavelength, and n represents the refractive index of the doped titanium oxide (TiO₂) electrode, the width or pitch (interval) of openings of the mask is preferably λ/(4n) to λ. Thus, unmasked portions are etched (through dry etching or wet etching, which may be selected as desired). The etching depth must be at least λ/(4n), and is preferably once to three times the pitch.

The method for forming an embossment on the TiO₂ electrode may be a method in which an embossment are formed during formation of a TiO₂ film; a method in which microdents and/or microprotrusions are randomly formed through etching of a TiO₂ film without formation of a mask; a method in which a photoresist mask pattern is formed on a TiO₂ film, and another TiO₂ film is formed on the pattern, followed by removal of unwanted portions together with the mask through the lift-off process; or a method in which a TiO₂ film is formed, and then the film is thermally treated, to thereby form an embossment randomly on the film surface.

An electrically conductive film or an insulating film may be formed on the surface of the doped titanium oxide (TiO₂) electrode having an embossment. Alternatively, an electrically conductive film and an insulating film may be sequentially formed on the embossed surface of the electrode.

As has been well known, there is a technique for removal of the epitaxial growth substrate. In the technique, a supporting substrate is bonded to an exposed semiconductor layer (e.g., a p-layer), and the epitaxial growth substrate, on which an n-layer is formed, is removed, whereby the surface of the n-layer is exposed. When the impurity-doped titanium oxide (TiO₂) electrode is formed on the exposed surface of the n-layer, the doped titanium oxide (TiO₂) electrode serves as an n-electrode. In this case, when at least one of a Bragg reflection layer formed of multiple transparent layers and a highly reflective metal layer is provided between the p-layer and the supporting substrate, the amount of light absorbed by the supporting substrate can be reduced.

### Embodiment 1

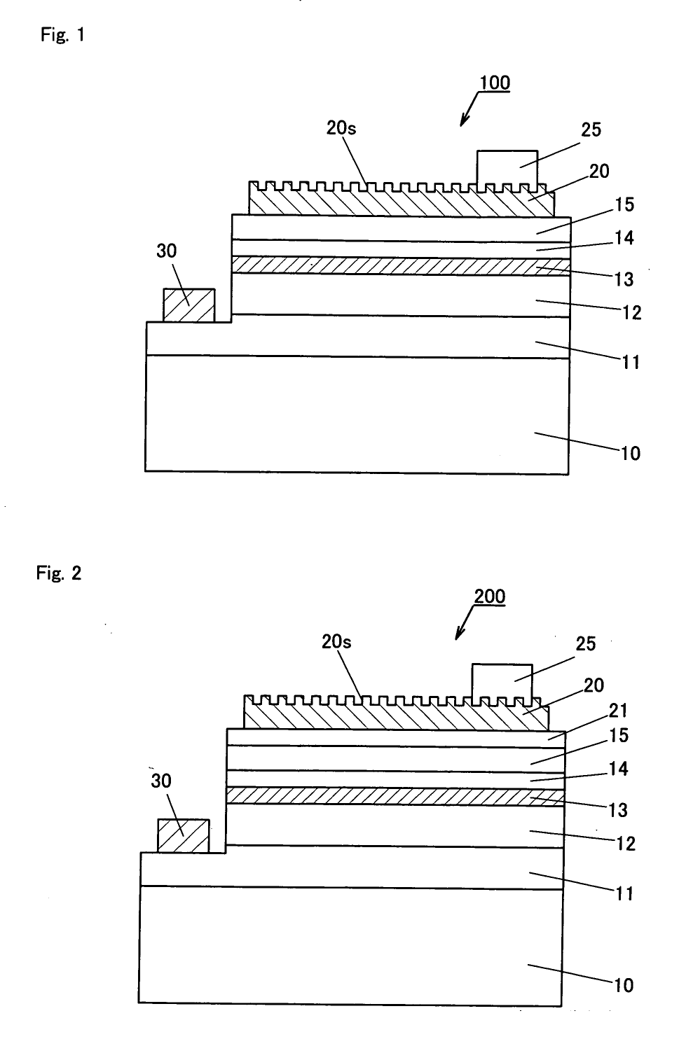

FIG. 1 is a cross-sectional view of the configuration of a Group III nitride-based compound semiconductor light-emitting device 100 according to Embodiment 1 of the present invention. The Group III nitride-based compound semiconductor light-emitting device 100 includes a sapphire substrate 10; an aluminum nitride (AlN) buffer layer (thickness: about 15 nm) (not illustrated) provided on the substrate 10; and a silicon (Si)-doped GaN n-contact layer 11 (thickness: about 4 μm) formed on the buffer layer. On the n-contact layer 11 is provided an n-cladding layer 12 (thickness: about 74 nm) formed of 10 layer units, each including an undoped In_{0.1}Ga_{0.9}N layer, an undoped GaN layer, and a silicon (Si)-doped GaN layer.

On the n-cladding layer 12 is provided a light-emitting layer 13 having a multiple quantum well (MQW) structure including alternately stacked eight well layers and eight barrier layers, in which each well layer is formed of an In_{0.2}Ga_{0.8}N layer (thickness: about 3 nm), and each barrier layer is formed of a GaN layer (thickness: about 2 nm) and an Al_{0.06}Ga_{0.94}N layer (thickness: 3 nm). On the light-emitting layer 13 is provided a p-cladding layer 14 (thickness: about 33 nm) of multiple layers of an init layer formed of a p-type Al_{0.3}Ga_{0.7}N layer and a p-type In_{0.08}Ga_{0.92}N layer. On the p-cladding layer 14 is provided a p-contact layer 15 (thickness: about 80 nm) having a layered structure including two p-type GaN layers having different magnesium concentrations.

On the p-contact layer 15 is provided a transparent electrode 20 made of niobium titanium oxide (niobium: 3 mol %) and having an embossment 20s, i.e., concave and convex configuration. An electrode 30 is provided on an exposed surface of the n-contact layer 11. The electrode 30 is formed of a vanadium (V) layer (thickness: about 20 nm) and an aluminum (Al) layer (thickness: about 2 μm). An electrode pad 25 made of a gold (Au) alloy is provided on a portion of the transparent electrode 20.

The niobium titanium oxide transparent electrode 20 is formed so as to have a thickness of 100 to 500 nm through sputtering or a similar technique. The thickness of the electrode 20 is preferably at least 100 nm, from the viewpoint of preventing an increase in diffusion resistance to current diffusing in a plane direction. The niobium titanium oxide transparent electrode 20 must be substantially transparent with respect to at least light emitted from the light-emitting layer 13.

The transparent electrode 20 may optionally have a rutile-type structure or an anatase-type structure. However, from the viewpoint of resistivity, the transparent electrode 20 preferably has an anatase-type structure.

The Group III nitride-based compound semiconductor light-emitting device 100 shown in FIG. 1 was produced as follows.

There were employed ammonia (NH₃) gas, a carrier gas (H₂ or N₂), trimethylgallium (TMG) gas, trimethylaluminum (TMA) gas, trimethylindium (TMI) gas, silane (SiH₄) gas, and cyclopentadienylmagnesium (Cp₂Mg) gas.

A single-crystal sapphire substrate 10 having an a-plane main surface was washed with an organic substance and thermally treated, and placed on a susceptor provided in a reaction chamber of an MOCVD apparatus. Subsequently, while H₂ was caused to flow through the reaction chamber at a flow rate of 2 L (liter)/minute at ambient pressure for about 30 minutes, the sapphire substrate 10 was baked at 1,100° C.

Subsequently, the temperature of the sapphire substrate 10 was lowered to 400° C., and H₂ (20 L/minute), NH₃ (10 L/minute), and TMA (1.8×10⁻⁵ mol/minute) were fed for about one minute, to thereby form an AlN buffer layer having a thickness of about 15 nm.

Subsequently, the temperature of the sapphire substrate 10 was maintained at 1,150° C., and H₂ (20 L/minute), NH₃ (10 L/minute), TMG (1.7×10⁻⁴ mol/minute), and silane which had been diluted with H₂ gas to 0.86 ppm (20×10⁻⁸ mol/minute) were fed for 40 minutes, to thereby form an n-type GaN n-contact layer 11 (thickness: about 4.0 μm, electron concentration: 2×10¹⁸/cm³, silicon concentration: 4×10¹⁸/cm³).

Subsequently, the temperature of the sapphire substrate 10 was maintained at 800° C.; N₂ or H₂ (10 L/minute) and NH₃ (10 L/minute) were fed; and the feed amounts of TMG, TMI, and silane which had been diluted with H₂ gas to 0.86 ppm were changed, to thereby form an n-cladding layer 12 (thickness: about 74 nm) including 10 layer units, each including an undoped In_{0.1}Ga_{0.9}N layer, an undoped GaN layer, and a silicon (Si)-doped GaN layer.

After formation of the n-cladding layer 12, the temperature of the sapphire substrate 10 was maintained at 770° C., and the feed amounts of TMG, TMI, and TMA were changed, to thereby form a light-emitting layer 13 having a multiple quantum well (MQW) structure including alternately stacked eight well layers and eight barrier layers, each of the well layers being formed of an In_{0.2}Ga_{0.8}N layer (thickness: about 3 nm), and each of the barrier layers being formed of a GaN layer (thickness: about 2 nm) and an Al_{0.06}Ga_{0.94}N layer (thickness: 3 nm).

Subsequently, the temperature of the sapphire substrate 10 was maintained at 840° C.; N₂ or H₂ (10 L/minute) and NH₃ (10 L/minute) were fed; and the feed amounts of TMG, TMI, TMA, and Cp₂Mg were changed, to thereby form a p-cladding layer 14 (thickness: about 33 nm) of multiple layers as an unit including a p-type Al_{0.3}Ga_{0.7}N layer and a p-type In_{0.08}Ga_{0.92}N layer.

Subsequently, the temperature of the sapphire substrate 10 was maintained at 1,000° C.; N₂ or H₂ (20 L/minute) and NH₃ (10 L/minute) were fed; and the feed amounts of TMG and Cp₂Mg were changed, to thereby form a p-contact layer 15 including two GaN layers having different magnesium (Mg) concentrations; i.e., a GaN layer having an Mg concentration of 5×10¹⁹/cm³ and a GaN layer having an Mg concentration of 1×10²⁰/cm³.

Subsequently, a photoresist was applied onto the p-type GaN layer 15, and an opening was provided in a predetermined region through photolithography. In an unmasked region, a portion of each of the p-type GaN layer 15, the p-cladding layer 14, the light-emitting layer 13, the n-cladding layer 12, and the n-type GaN layer 11 was etched through reactive ion etching employing a chlorine-containing gas, so that a surface of the n-type GaN layer 11 was exposed. Subsequently, the photoresist mask was removed. Thereafter, through the procedures described below, an n-electrode 30 was formed on the n-type GaN layer 11, and a p-electrode 20 was formed on the p-type GaN layer 15.

A niobium titanium oxide transparent electrode (p-electrode) 20 (thickness: 200 nm) was formed on the entire top surface of the resultant wafer through pulsed laser deposition. The ratio by mole of niobium to titanium was regulated to 3%.

Subsequently, a photoresist was applied to the p-electrode 20, and the photoresist mask formed on the p-electrode 20 was patterned through photolithography, followed by dry etching so that the p-electrode 20 had a predetermined shape.

Subsequently, a photoresist was applied onto the exposed surface of the n-type GaN layer 11, and an opening was provided in a predetermined region through photolithography. Thereafter, an n-electrode 30 was formed on the n-type GaN layer 11 through vacuum deposition under vacuum on the order of 10⁻⁶ Torr or less.

Subsequently, the photoresist was removed through the lift-off process so that the n-electrode 30 had a predetermined shape. Thereafter, thermal treatment was carried out in a nitrogen-containing atmosphere at 600° C. for five minutes, to thereby alloy the n-electrode 30 with the n-type GaN layer 11, and to reduce electrical resistance of the p-type GaN layer 15 and the p-cladding layer 14.

Subsequently, in order to form an embossment 20s on the transparent electrode 20, a photoresist was applied onto the electrode 20, and the photoresist mask was patterned through photolithography. With respect to an emission wavelength of 470 nm, the diameter of circular openings provided in the mask was regulated to 2 μm, and the pitch between adjacent openings was regulated to 1 μm. Subsequently, unmasked portions were dry-etched so as to attain an etching depth of 150 nm.

### COMPARATIVE EMBODIMENT

There was produced a Group III nitride-based compound semiconductor light-emitting device having the same configuration as the light-emitting device 100 shown in FIG. 1, except that the transparent electrode made of niobium titanium oxide (niobium: 3 mol %) does not have an embossment 20s; i.e., the exposed surface of the electrode is flat. The thus-produced light-emitting device was compared with the light-emitting device 100 in terms of light output. The Group III nitride-based compound semiconductor light-emitting device 100 shown in FIG. 1, which has the an embossment 20s, was found to have a light output higher by 30% than that of the Group III nitride-based compound semiconductor light-emitting device not having an embossment 20s. There was no difference in any other device characteristic (e.g., drive voltage) between these light-emitting devices.

### Embodiment 2

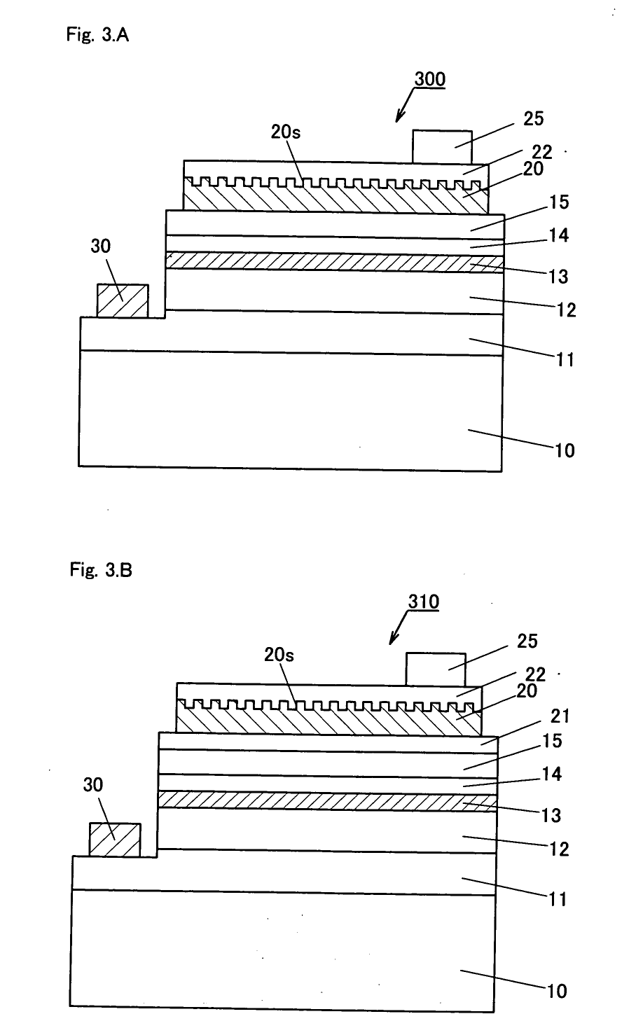

FIG. 2 is a cross-sectional view of the configuration of a Group III nitride-based compound semiconductor light-emitting device 200 according to Embodiment 2 of the present invention. The Group III nitride-based compound semiconductor light-emitting device 200 shown in FIG. 2 has the same configuration as the Group III nitride-based compound semiconductor light-emitting device 100 shown in FIG. 1, except that a transparent, electrically conductive layer 21 made of indium tin oxide (ITO) and having a thickness of 50 nm (i.e., less than 1/(4n) of the emission wavelength (470 nm) in the air of the light emitted from the light-emitting layer 13 (wherein n represents the refractive index of ITO)) is provided between the p-type GaN layer 15 and the transparent electrode 20 made of niobium titanium oxide (niobium: 3 mol %). The transparent, electrically conductive layer 21 made of ITO having low resistivity is envisaged to exhibit the effect of reducing the diffusion resistance (in a plane direction) of the positive electrode, as well as the effect of reducing contact resistance between the electrode and the p-type GaN layer 15. Since the thickness of the transparent, electrically conductive layer 21 made of ITO is less than 1/(4n) of the emission wavelength of the light-emitting layer 13, total reflection of light is less likely to occur at the interface between the transparent, electrically conductive layer 21 made of ITO having low refractive index and the p-type GaN layer 15 having high refractive index, and light absorption occurs only to a negligible extent. Therefore, light extraction performance is not reduced.

### Embodiment 3

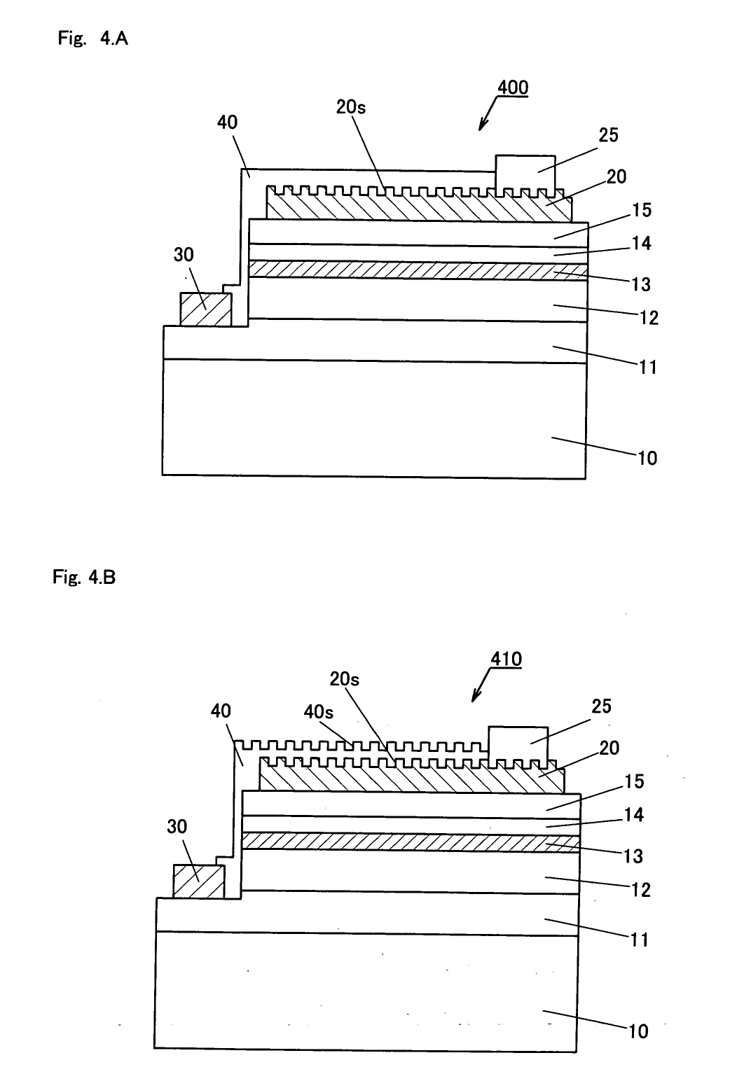

FIG. 3A is a cross-sectional view of the configuration of a Group III nitride-based compound semiconductor light-emitting device 300 according to Embodiment 3 of the present invention. The Group III nitride-based compound semiconductor light-emitting device 300 shown in FIG. 3A has the same configuration as the Group III nitride-based compound semiconductor light-emitting device 100 shown in FIG. 1, except that the top surface of the transparent electrode 20 made of niobium titanium oxide (niobium: 3 mol %) is covered with a transparent, electrically conductive layer 22 made of indium tin oxide (ITO) and having a thickness of 200 nm. By virtue of addition of the transparent, electrically conductive layer 22 made of ITO, the diffusion resistance (in a plane direction) of the positive electrode can be reduced. FIG. 3B is a cross-sectional view of the configuration of a Group III nitride-based compound semiconductor light-emitting device 310, which is a modification of Embodiment 3. The Group III nitride-based compound semiconductor light-emitting device 310 shown in FIG. 3B has the same configuration as the Group III nitride-based compound semiconductor light-emitting device 200 shown in FIG. 2, except that the top surface of the transparent electrode 20 made of niobium titanium oxide (niobium: 3 mol %) is covered with a transparent, electrically conductive layer 22 made of indium tin oxide (ITO) and having a thickness of 200 nm. By virtue of addition of the transparent, electrically conductive layer 22 made of ITO, the diffusion resistance (in a plane direction) of the positive electrode can be reduced.

### Embodiment 4

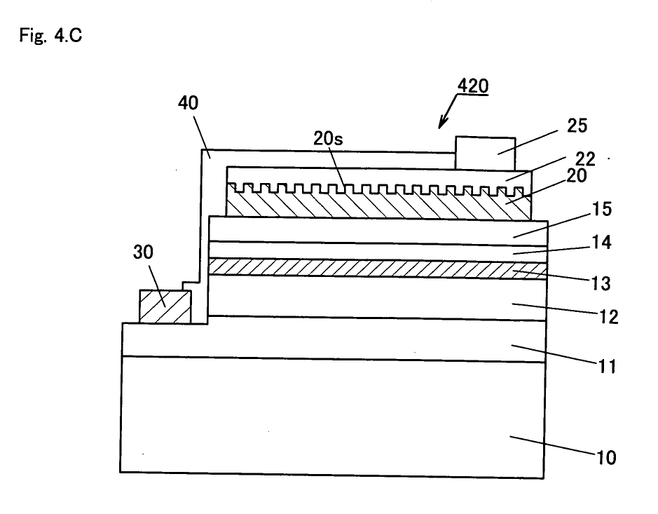

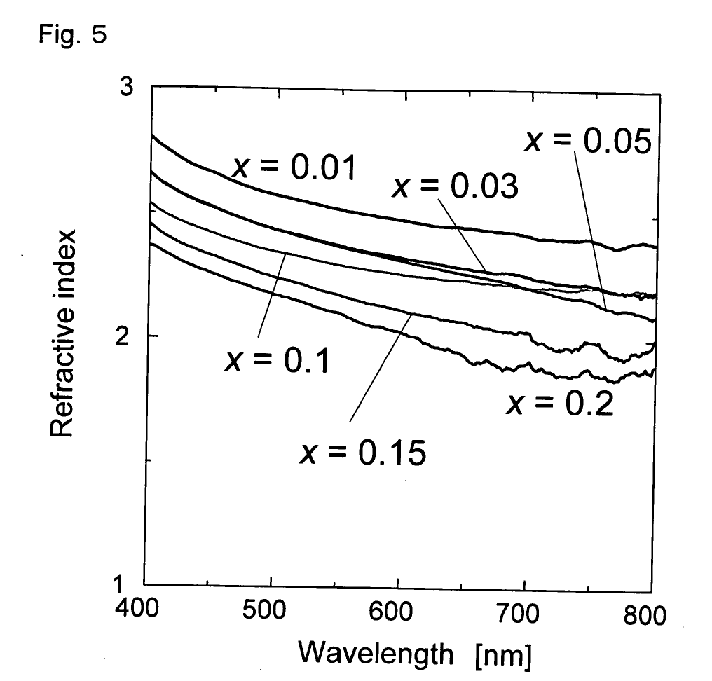

FIG. 4A is a cross-sectional view of the configuration of a Group III nitride-based compound semiconductor light-emitting device 400 according to Embodiment 4 of the present invention. The Group III nitride-based compound semiconductor light-emitting device 400 shown in FIG. 4A has the same configuration as the Group III nitride-based compound semiconductor light-emitting device 100 shown in FIG. 1, except that the top surface of the transparent electrode 20 made of niobium titanium oxide (niobium: 3 mol %) is covered with a protective film 40 made of silicon dioxide (SiO₂) and having a thickness of 500 nm.

FIG. 4B is a cross-sectional view of the configuration of a Group III nitride-based compound semiconductor light-emitting device 410, which is a modification of Embodiment 4. The Group III nitride-based compound semiconductor light-emitting device 410 shown in FIG. 4B has the same configuration as the Group III nitride-based compound semiconductor light-emitting device 400 shown in FIG. 4A, except that an embossment 40s are provided on the top surface of the protective film 40 made of silicon dioxide (SiO₂). The Group III nitride-based compound semiconductor light-emitting device 410 shown in FIG. 4B, which has the embossment 40s on the top surface of the protective film 40, realizes further improvement of light extraction performance, as compared with the Group III nitride-based compound semiconductor light-emitting device 400 shown in FIG. 4A, which does not have an embossment on the top surface of the protective film 40.

FIG. 4C is a cross-sectional view of the configuration of a Group III nitride-based compound semiconductor light-emitting device 420, which is another modification of Embodiment 4. The Group III nitride-based compound semiconductor light-emitting device 420 shown in FIG. 4C has the same configuration as the Group III nitride-based compound semiconductor light-emitting device 300 shown in FIG. 3A, except that the top surface of the transparent, electrically conductive layer 22 made of ITO is covered with a protective film 40 made of silicon oxide (SiO₂) and having a thickness of 500 nm.

Similar to the case of the silicon oxide (SiO₂) protective film 40 of the Group III nitride-based compound semiconductor light-emitting device 410 shown in FIG. 4B, an embossment 40s may be provided on the top surface of the silicon oxide (SiO₂) protective film 40 of the Group III nitride-based compound semiconductor light-emitting device 420 shown in FIG. 4C.

The Group III nitride-based compound semiconductor light-emitting device 310 shown in FIG. 3B may further include the silicon oxide (SiO₂) protective film 40 of the Group III nitride-based compound semiconductor light-emitting device 420 shown in FIG. 4C, or the silicon oxide (SiO₂) protective film 40 having the embossment 40s of the Group III nitride-based compound semiconductor light-emitting device 410 shown in FIG. 4B.

In each of the aforementioned Embodiments, niobium (Nb) is added singly to titanium oxide. However, tantalum (Ta) may be added singly to titanium oxide, or niobium (Nb) and tantalum (Ta) may be added together to titanium oxide.

What is claimed is:

1. A Group III nitride-based compound semiconductor light-emitting device having a transparent electrode, wherein the transparent electrode comprises titanium oxide which is doped with at least one selected from a group consisting of niobium (Nb), tantalum (Ta), molybdenum (Mo), arsenic (As), antimony (Sb), aluminum (Al), and tungsten (W) at a ratio by mole with respect to titanium (Ti) of 1 to 10%, and the transparent electrode has, on at least a portion thereof, an embossment.

2. A Group III nitride-based compound semiconductor light-emitting device as described in claim 1, wherein the transparent electrode comprises at least one selected from a group consisting of niobium titanium oxide and tantalum titanium oxide in which the ratio by mole of niobium (Nb) and tantalum (Ta) to titanium (Ti) is 3 to 10%, respectively.

3. A Group III nitride-based compound semiconductor light-emitting device as described in claim 1, which has a Group III nitride-based compound semiconductor contact layer, and, between the transparent electrode and the contact layer, there is no such a layer that is made of a material other than a material of the contact layer and the transparent electrode.

4. A Group III nitride-based compound semiconductor light-emitting device as described in claim 2, which has a Group III nitride-based compound semiconductor contact layer, and, between the transparent electrode and the contact layer, there is no such a layer that is made of a material other than a material of the contact layer and the transparent electrode.

5. A Group III nitride-based compound semiconductor light-emitting device as described in claim 3, wherein the transparent electrode is in contact with the contact layer, and the ratio of the refractive index of the transparent electrode to that of the contact layer is 0.98 to 1.02.

6. A Group III nitride-based compound semiconductor light-emitting device as described in claim 4, wherein the transparent electrode is in contact with the contact layer, and the ratio of the refractive index of the transparent electrode to that of the contact layer is 0.98 to 1.02.

7. A Group III nitride-based compound semiconductor light-emitting device as described in claim 1, which has a Group III nitride-based compound semiconductor contact layer, and has, between the transparent electrode and the contact layer, only a transparent, electrically conductive layer which is made of a material other than a material of the contact layer and the transparent electrode and which has a thickness that is one quarter or less the wavelength of an emitted light in the transparent, electrically conductive layer.

8. A Group III nitride-based compound semiconductor light-emitting device as described in claim 2, which has a Group III nitride-based compound semiconductor contact layer, and has, between the transparent electrode and the contact layer, only a transparent, electrically conductive layer which is made of a material other than a material of the contact layer and the transparent electrode and which has a thickness that is one quarter or less the wavelength of an emitted light in the transparent, electrically conductive layer.

9. A Group III nitride-based compound semiconductor light-emitting device as described in claim 1, wherein the transparent electrode is a p-electrode.

10. A Group III nitride-based compound semiconductor light-emitting device as described in claim 2, wherein the transparent electrode is a p-electrode.

11. A Group III nitride-based compound semiconductor light-emitting device as described in claim 5, wherein the transparent electrode is a p-electrode.

12. A Group III nitride-based compound semiconductor light-emitting device as described in claim 6, wherein the transparent electrode is a p-electrode.

13. A Group III nitride-based compound semiconductor light-emitting device as described in claim 7, wherein the transparent electrode is a p-electrode.

14. A Group III nitride-based compound semiconductor light-emitting device as described in claim 8, wherein the transparent electrode is a p-electrode.

15. A Group III nitride-based compound semiconductor light-emitting device as described in claim 1, wherein the transparent electrode is an n-electrode.

16. A Group III nitride-based compound semiconductor light-emitting device as described in claim 2, wherein the transparent electrode is an n-electrode.

17. A Group III nitride-based compound semiconductor light-emitting device as described in claim 5, wherein the transparent electrode is an n-electrode.

18. A Group III nitride-based compound semiconductor light-emitting device as described in claim 6, wherein the transparent electrode is an n-electrode.

19. A Group III nitride-based compound semiconductor light-emitting device as described in claim 7, wherein the transparent electrode is an n-electrode.

20. A Group III nitride-based compound semiconductor light-emitting device as described in claim 8, wherein the transparent electrode is an n-electrode.
